(19) United States
(12) Patent Application Publication
(10) Pub. No.: US 2024/0186389 A1
(43) Pub. Date: Jun. 6, 2024

(54) SEMICONDUCTOR STRUCTURE AND MANUFACTURING METHOD THEREOF

(71) Applicant: Advanced Power Electronics Corp., Hsinchu County (TW)

(72) Inventor: Yen-Yuan HUANG, Hsinchu County (TW)

(21) Appl. No.: 18/485,332

(22) Filed: Oct. 12, 2023

(30) Foreign Application Priority Data
Dec. 1, 2022 (TW) 111146247

(51) Int. Cl. H01L 29/423; H01L 29/06; H01L 29/417; H01L 29/66; H01L 29/78

(52) U.S. Cl. CPC H01L 29/4236; H01L 29/0684; H01L 29/41741; H01L 29/66666; H01L 29/7827

(57) ABSTRACT

A semiconductor structure includes a first insulating layer, a floating portion, a second insulating layer, two source regions, and a first gate region. The first insulating layer is disposed in a trench of a semiconductor substrate. The floating portion is disposed in the first insulating layer. The floating portion has a first portion and a second portion extending from the first portion. The first insulating layer surrounds the first portion. The second insulating layer is disposed on the first insulating layer and extends to a top surface of the semiconductor substrate. The second insulating layer covers the second portion. The two source regions are disposed in the second insulating layer. The two source regions are separated by the second insulating layer and are disposed symmetrically along a longitudinal direction of the trench. The first gate region is disposed over the two source regions.

### CROSS-REFERENCE TO RELATED APPLICATION

This application claims priority to Taiwan Application Serial Number 111146247, filed Dec. 1, 2022, which is herein incorporated by reference.

### BACKGROUND

### Technical Field

The present disclosure relates to a semiconductor structure and a manufacturing method of a semiconductor structure.

### Description of Related Art

Generally speaking, a shielded gate trench type metal-oxide-semiconductor field effect transistor (SGT-MOSFET) has a low on-resistance. Therefore, it has the advantage of significantly reducing power consumption and is widely used in high-frequency and low-voltage power devices. However, since a SGT-MOSFET has a trench structure, the filling of electrode materials is susceptible to the shape of the trench structure or the type of electrode materials. In turn, the trench structure affects the device reliability of the SGT-MOSFET and the electrical characteristics of the electrodes.

Accordingly, how to provide a semiconductor structure and a manufacturing method of a semiconductor structure to solve the aforementioned problems becomes an important issue to be solved by those in the industry.

### SUMMARY

An aspect of the disclosure is to provide a semiconductor structure and a manufacturing method of a semiconductor structure that may efficiently solve the aforementioned problems.

According to an embodiment of the disclosure, a semiconductor structure includes a first insulating layer, a floating portion, a second insulating layer, two source regions, and a first gate region. The first insulating layer is disposed in a trench of a semiconductor substrate. The floating portion is disposed in the first insulating layer. The floating portion has a first portion and a second portion extending from the first portion. The first insulating layer surrounds the first portion of the floating portion. The second insulating layer is disposed on the first insulating layer and extends to a top surface of the semiconductor substrate. The second insulating layer covers the second portion of the floating portion. The two source regions are disposed in the second insulating layer. The two source regions are separated by the second insulating layer and are disposed symmetrically along a longitudinal direction of the trench. The first gate region is disposed over the two source regions.

In an embodiment of the disclosure, the semiconductor structure further includes a second gate region. The second gate region is disposed over the two source regions. The first gate region and the second gate region align with the two source regions, respectively. The first gate region and the second gate region are separated by the second insulating layer and are disposed symmetrically along the longitudinal direction of the trench.

In an embodiment of the disclosure, a width of the first gate region is greater than a sum of widths of the two source regions.

In an embodiment of the disclosure, the semiconductor substrate has an implantation region. A position of the implantation region corresponds to a position of the first gate region.

In an embodiment of the disclosure, the semiconductor structure further includes a metal contact and a third insulating layer. The metal contact extends into the semiconductor substrate to contact the implantation region of the semiconductor substrate. The third insulating layer is disposed between the first gate region and the metal contact.

In an embodiment of the disclosure, the semiconductor structure further includes a second gate region. The second gate region is disposed over the two source regions. The third insulating layer covers the first gate region and the second region.

In an embodiment of the disclosure, the third insulating layer covers the first gate region.

In an embodiment of the disclosure, the floating portion comprises polysilicon.

According to another embodiment of the disclosure, a manufacturing method of a semiconductor structure includes forming a first insulating layer in a trench of a semiconductor substrate. The manufacturing method further includes forming a floating portion in the first insulating layer. The floating portion has a first portion and a second portion extending from the first portion. The manufacturing method further includes etching the first insulating layer by wet etching to expose the second portion of the floating portion. The manufacturing method further includes forming a second insulating layer on the first insulating layer by wet oxidation. A part of the second portion of the floating portion is converted to the second insulating layer. The manufacturing method further includes forming two source regions in the trench. The two source regions are separated by the second insulating layer. The two source regions are disposed symmetrically along a longitudinal direction of the trench. The manufacturing method further includes forming a first gate region over the two source regions.

In an embodiment of the disclosure, the manufacturing method further includes forming a second gate region over the two source regions. The first gate region and the second gate region align with the two source regions, respectively. The first gate region and the second gate region are separated by the second insulating layer and are disposed symmetrically along the longitudinal direction of the trench.

In an embodiment of the disclosure, a width of the first gate region is greater than a sum of widths of the two source regions.

In an embodiment of the disclosure, the manufacturing method further includes etching the second insulating layer after forming the two source regions in the trench such that a top surface of the second insulating layer is level with a top surface of one of the two source regions.

In an embodiment of the disclosure, the manufacturing method further includes implanting a top surface of the semiconductor substrate such that the semiconductor substrate has an implantation region. A position of the implantation region corresponds to a position of the first gate region.

In an embodiment of the disclosure, the manufacturing method further includes forming a third insulating layer on the first gate region. The third insulating layer covers the first gate region. The manufacturing method further includes forming a metal contact on the third insulating layer. The metal contact extends into the semiconductor substrate to contact the implantation region of the semiconductor substrate.

In an embodiment of the disclosure, polysilicon is used to form the floating portion in the first insulating layer.

Accordingly, in the semiconductor structure and the manufacturing method of the semiconductor structure of the present disclosure, by separating the two source regions of the semiconductor structure with the second insulating layer and by disposing the gate region(s) over the two source regions, structural defects may be avoided when forming the gate region(s). In addition, the two source regions disposed symmetrically along the longitudinal direction can enhance the electrical characteristics of the semiconductor structure. Therefore, the device reliability of the semiconductor structure may be improved. Moreover, by disposing the floating portion below the two source regions of the semiconductor structure, capacitance caused by the structural defects of the semiconductor structure may be reduced, thereby improving the performance of the semiconductor structure.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial cross-sectional view of a semiconductor structure at one view angle according to an embodiment of the disclosure;

FIG. 2 is a partial cross-sectional view of a semiconductor structure at one view angle according to another embodiment of the disclosure;

FIG. 3 is a partial cross-sectional view of the semiconductor structure in FIG. 1 at another view angle according to an embodiment of the disclosure;

FIG. 4 is a flow chart of a manufacturing method of a semiconductor structure according to an embodiment of the disclosure;

FIG. 5, FIG. 6, FIG. 7, FIG. 8, and FIG. 9 are partial cross-sectional views of different intermediate stages of a manufacturing method at one view angle according to an embodiment of the disclosure;

FIG. 10 and FIG. 11 are partial cross-sectional views of different intermediate stages of a manufacturing method at one view angle according to another embodiment of the disclosure; and

FIG. 12, FIG. 13, FIG. 14, and FIG. 15 are partial cross-sectional views of different intermediate stages of a manufacturing method at another view angle according to an embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

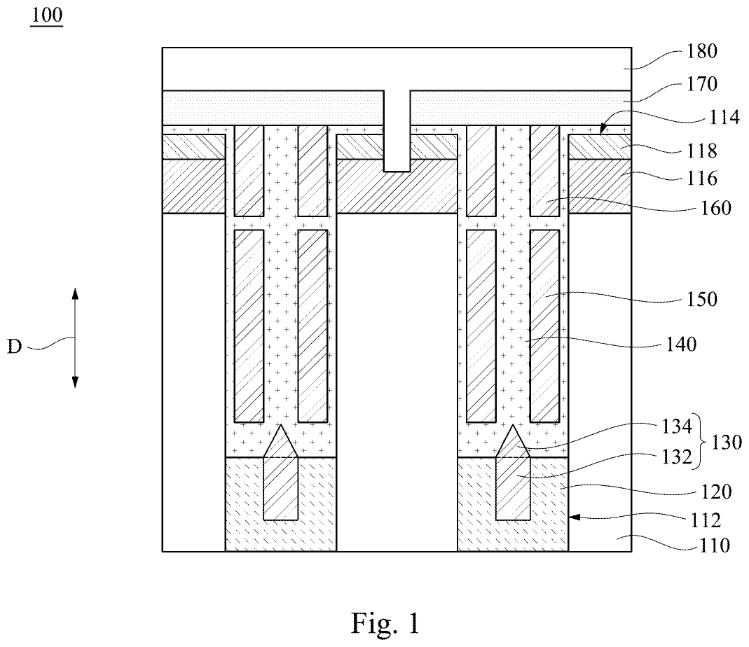

Reference is made to FIG. 1. FIG. 1 illustrates a partial cross-sectional view of a semiconductor structure 100 at one view angle according to an embodiment of the present disclosure. For example, the semiconductor structure 100 may be applied to high-frequency and low-voltage power devices, such as shielded gate trench type metal oxide semi-field effect transistors (SGT-MOSFETs). The semiconductor structure 100 has a lower on-resistance. Therefore, it has the advantage of reducing power consumption. As shown in FIG. 1, the semiconductor structure 100 includes a semiconductor substrate 110, a first insulating layer 120, a floating portion 130, a second insulating layer 140, two source regions 150, and two gate regions 160. The semiconductor substrate 110 has a trench 112 and a top surface 114. The first insulating layer 120 of the semiconductor structure 100 is disposed in the trench 112 of the semiconductor substrate 110. The floating portion 130 of the semiconductor structure 100 is disposed in the first insulating layer 120 of the semiconductor structure 100. The floating portion 130 of the semiconductor structure 100 has a first portion 132 and a second portion 134 extending from the first portion 132. In some embodiments, the material of the floating portion 130 of the semiconductor structure 100 may include polysilicon.

In some embodiments, as shown in FIG. 1, the first insulating layer 120 of the semiconductor structure 100 surrounds the first portion 132 of the floating portion 130. The second insulating layer 140 of the semiconductor structure 100 is disposed on the first insulating layer 120 and extends to the top surface 114 of the semiconductor substrate 110. In this embodiment, the second portion 134 of the floating portion 130 including polysilicon can be partially converted to the second insulating layer 140, for example, the second insulating layer 140 between the two source regions 150, by wet oxidation. Additionally, the second insulating layer 140 may cover the remaining second portion 134 of the floating portion 130, as shown in FIG. 1. The two source regions 150 of the semiconductor structure 100 are disposed in the second insulating layer 140 of the semiconductor structure 100. It should be noted that the two source regions 150 are separated by the second insulating layer 140 and disposed symmetrically along a longitudinal direction D of the trench 112 of the semiconductor substrate 110, as shown in FIG. 1. In detail, the two source regions 150 are separated by the second insulating layer 140 to which the second portion 134 of the floating portion 130 is partially converted by wet oxidation.

In this embodiment, the semiconductor substrate 110 includes two gate regions 160. The two gate regions 160 are disposed over the two source regions 150. It should be noted that the two gate regions 160 align with the two source regions 150, respectively. On top of that, the two gate regions 160 are separated by the second insulating layer 140. In some embodiments, the two source regions 150 and the two gate regions 160 of the semiconductor structure 100 may be disposed symmetrically along the longitudinal direction D of the trench 112 of the semiconductor substrate 110. For example, the longitudinal direction D of the trench 112 of the semiconductor substrate 110 may be a vertical direction. That is to say, the two source regions 150 and the two gate regions 160 may be disposed symmetrically along the vertical direction, as shown in FIG. 1. The two source regions 150 and the two gate regions 160 are separated by the second insulating layer 140. Specifically, the two source regions 150 and the two gate regions 160 are separated by the second insulating layer 140 to which the second portion 134 of the floating portion 130 is partially converted by wet oxidation.

To be more specific, the two source regions 150 of the semiconductor structure 100 are separated by the second insulating layer 140 and the two gate regions 160 are disposed over the two source regions 150. Therefore, structural defects may be avoided when forming the two gate regions 160. In addition, the two source regions 150 and the two gate regions 160 of the semiconductor structure 100 disposed symmetrically along the longitudinal direction D of the trench 112 of the semiconductor structure 100 can enhance the electrical characteristics of the semiconductor structure 100, thereby improving the device reliability of the semiconductor structure 100. Moreover, by disposing the floating portion 130 below the two source regions 150 of the semiconductor structure 100, capacitance caused by the structural defects of the semiconductor structure 100 may be reduced. Thus, the performance of the semiconductor structure 100 may be improved.

In some embodiments, the semiconductor substrate 110 of the semiconductor structure 100 has an implantation region. For example, the implantation region may include a P-type region 116 and an N-type region 118, as shown in FIG. 1. In some embodiments, positions of the P-type region 116 and the N-type region 118 of the semiconductor substrate 110 correspond to positions of the two gate regions 160. In other words, the P-type region 116 and the N-type region 118 of the semiconductor substrate 110 are aligned with the two gate regions 160, as shown in FIG. 1. Moreover, in some embodiments, the semiconductor structure 100 further includes a third insulating layer 170 and a metal contact 180. The third insulating layer 170 of the semiconductor structure 100 is disposed between the two gate regions 160 and the metal contact 180. The metal contact 180 of the semiconductor structure 100 extends into the semiconductor substrate 110 to contact the implantation region of the semiconductor substrate 110 (i.e., the P-type region 116 and the N-type region 118).

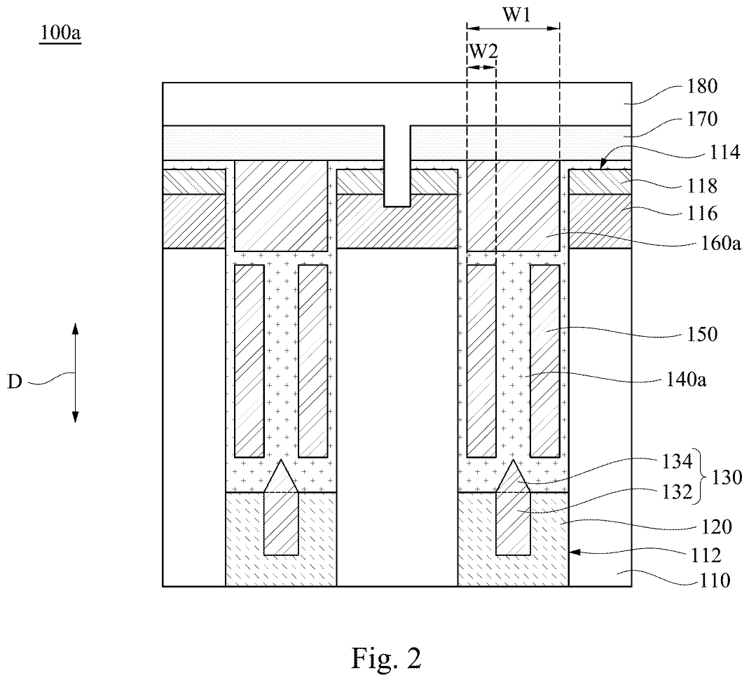

Reference is made to FIG. 2. FIG. 2 illustrates a partial cross-sectional view of a semiconductor structure 100a at one view angle according to another embodiment of the present disclosure. The difference between the semiconductor structure 100 in FIG. 1 and the semiconductor structure 100a in FIG. 2 lies in that the semiconductor structure 100a includes a second insulating layer 140a and a gate region 160a, instead of the second insulating layer 140 and the two gate regions 160 of the semiconductor structure 100 shown in FIG. 1. The gate region 160a is not separated by the second insulating layer 140a. That is to say, the second insulating layer 140a does not extend into the gate region 160a, as shown in FIG. 2. Furthermore, a width W1 of the gate region 160a of the semiconductor structure 100a is greater than a sum of widths W2 of the two source regions 150 of the semiconductor structure 100a, as shown in FIG. 2.

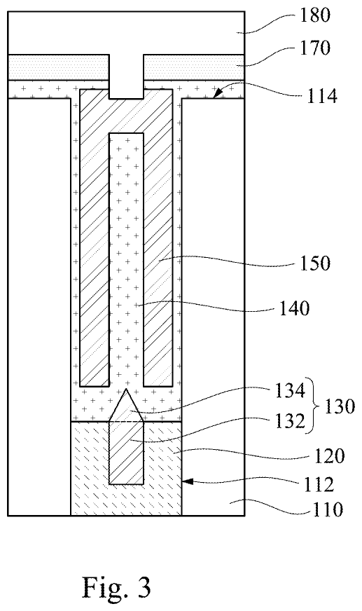

Reference is made to FIG. 3. FIG. 3 illustrates a partial cross-sectional view of the semiconductor structure 100 shown in FIG. 1 at another view angle according to an embodiment of the present disclosure. In detail, FIG. 3 illustrates a partial cross-sectional view of a contact of the two source regions 150 of the semiconductor structure 100. As shown in FIG. 3, the first insulating layer 120 of the semiconductor structure 100 is disposed in the trench 112 of the semiconductor substrate 110. The floating portion 130 of the semiconductor structure 100 is disposed in the first insulating layer 120. In some embodiments, the material of the floating portion 130 may include polysilicon. The two source regions 150 are disposed over the floating portion 130. The second insulating layer 140 of the semiconductor structure 100 is disposed on the first insulating layer 120. In some embodiments, the third insulating layer 170 of the semiconductor structure 100 is disposed between the second insulating layer 140 and the metal contact 180. The metal contact 180 extends into the semiconductor substrate 110 to contact the two source regions 150, as shown in FIG. 3.

It should be understood that the connections between the components and the functions of the components that have been described will not be repeated. In the following paragraphs, a manufacturing method of a semiconductor structure will be described.

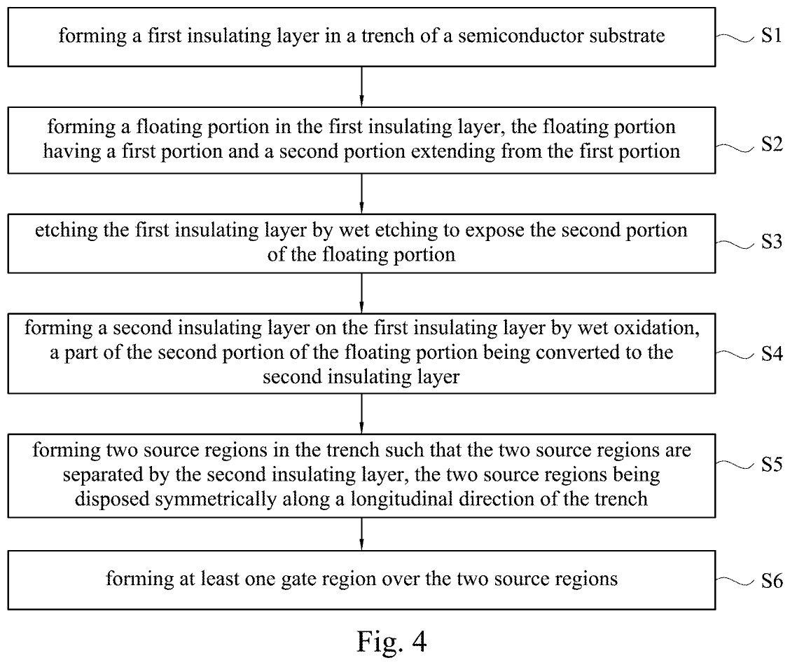

Reference is made to FIG. 4. FIG. 4 illustrates a flow chart of a manufacturing method of a semiconductor structure according to an embodiment of the present disclosure. As shown in FIG. 4, the manufacturing method includes the following steps. First, in the step S1, a first insulating layer is formed in a trench of a semiconductor substrate. Second, in the step S2, a floating portion is formed in the first insulating layer. After the step S2 is finished, the floating portion has a first portion and a second portion extending from the first portion. Then, in the step S3, the first insulating layer is etched by wet etching to expose the second portion of the floating portion. Later on, in the step S4, a second insulating layer is formed on the first insulating layer by wet oxidation. After the step S4 is conducted, the second portion of the floating portion is converted to the second insulating layer. Next, in the step S5, two source regions are formed in the trench. The two source regions are separated by the second insulating layer. In addition, the two source regions are disposed symmetrically along a longitudinal direction of the trench. In the end, in the step S6, at least one gate region is formed over the two source regions. In the following paragraphs, each of the aforementioned steps will be explained in detail.

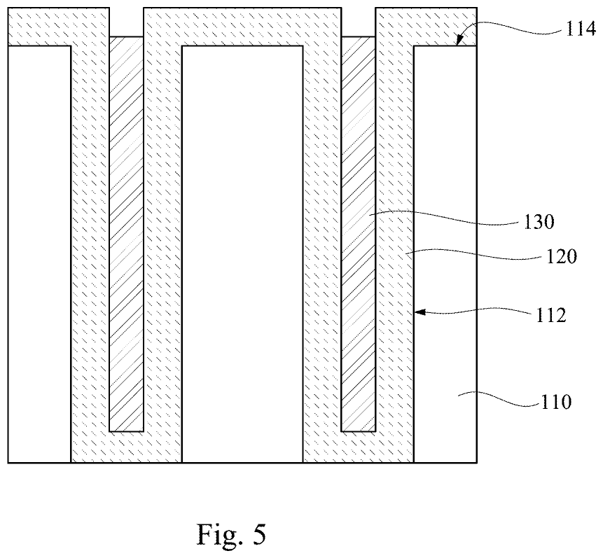

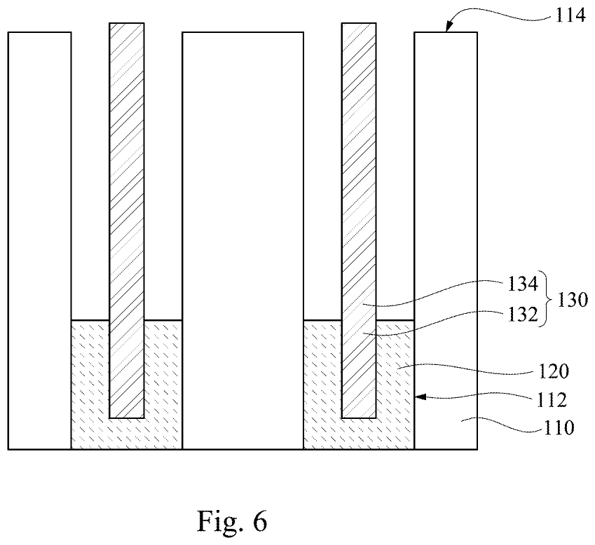

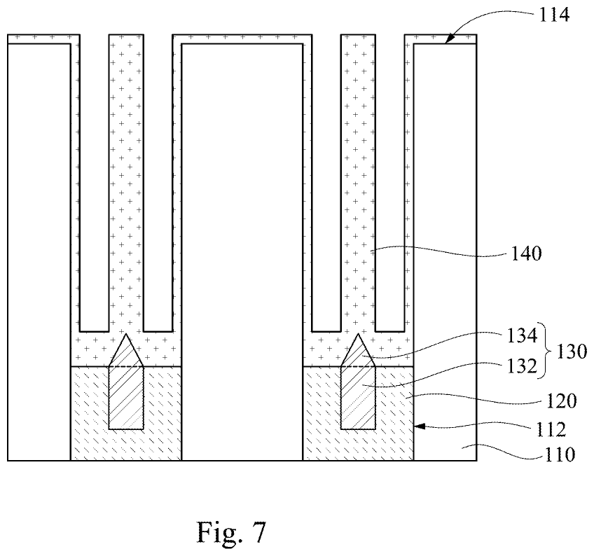

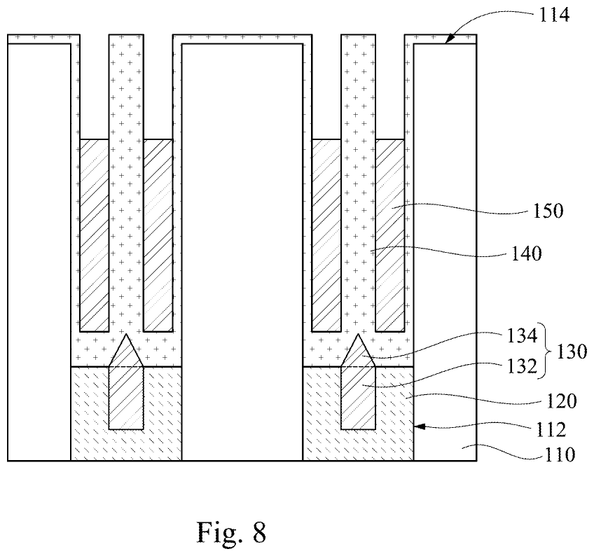

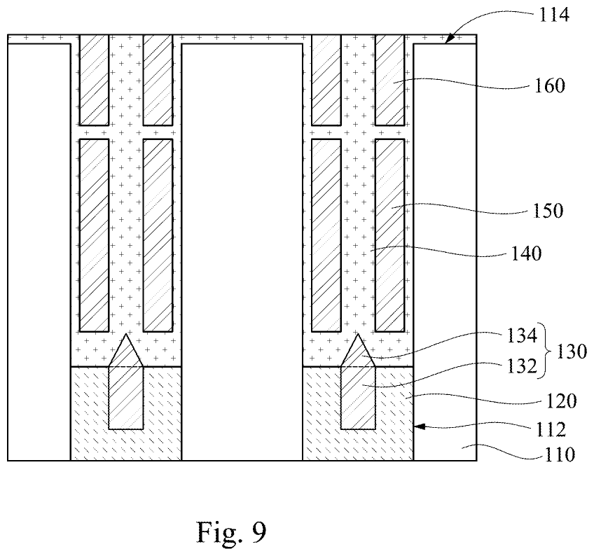

FIG. 5, FIG. 6, FIG. 7, FIG. 8, and FIG. 9 illustrate partial cross-sectional views of different intermediate stages of the manufacturing method at one view angle according to an embodiment of the present disclosure. In detail, FIG. 5, FIG. 6, FIG. 7, FIG. 8, and FIG. 9 illustrate partial cross-sectional views of the semiconductor structure 100 shown in FIG. 1 at different intermediate stages of the manufacturing method. Reference is made to FIG. 5. As shown in FIG. 5, a trench 112 may be first formed in a semiconductor substrate 110 by an etching process. Next, a first insulating layer 120 may be formed in the trench 112 and on a top surface 114 of the semiconductor substrate 110. For example, oxide may be used to form the first insulating layer 120. However, it is not limited thereto. After forming the first insulating layer 120, a floating portion 130 may be formed in the first insulating layer 120. In this embodiment, polysilicon is used to form the floating portion 130 in the first insulating layer 120.

Reference is made to FIG. 6 and FIG. 7. As shown in FIG. 6 and FIG. 7, after the floating portion 130 is formed in the first insulating layer 120, the first insulating layer 120 can be etched back by wet etching to expose the second portion 134 of the floating portion 130 and the top surface 114 of the semiconductor substrate 110. After exposing the second portion 134 of the floating portion 130, the second insulating layer 140 may be formed on the first insulating layer 120 by wet oxidation. A part of the second portion 134 of the floating portion 130 is converted to the second insulating layer 140. In detail, in the wet oxidation process, the second portion 134 of the floating portion 130 including polysilicon can be partially converted to the second insulating layer 140. In addition, a ratio of a formation rate of the second insulating layer 140 on the second portion 134 of the floating portion 130 including polysilicon to a formation rate of the second insulating layer 140 on sidewalls of the trench 112 is about 3:1. In other words, the second insulating layer 140 forms faster on the second portion 134 of the floating portion 130 than on the sidewalls of the trench 112.

Reference is made to FIG. 8 and FIG. 9. As shown in FIG. 8 and FIG. 9, after forming the second insulating layer 140, two source regions 150 can be formed in the second insulating layer 140. The two source regions 150 are separated by the second insulating layer 140, as shown in FIG. 8 and FIG. 9. This configuration helps avoid structural defects occurred during the formation of the two source regions 150. In some embodiments, polysilicon may be used to form the two source regions 150 in the second insulating layer 140. In this embodiment, the semiconductor structure 100 includes two gate regions 160. Hence, after forming the two source regions 150, the two gate regions 160 are formed over the two source regions 150. The two gate regions 160 align with the two source regions 150, respectively. The two gate regions 160 are separated by the second insulating layer 140.

Referring back to FIG. 1, after the two gate regions 160 are formed, the top surface 114 of the semiconductor substrate 110 can be implanted such that the semiconductor substrate 110 has an implantation region. For example, in some embodiments, the implantation region may include a P-type region 116 and an N-type region 118. In some embodiments, positions of the P-type region 116 and the N-type region 118 of the semiconductor substrate 110 correspond to positions of the two gate regions 160. As shown in FIG. 1, after the semiconductor substrate 110 is implanted, a third insulating layer 170 may be formed on the two gate regions 160. The third insulating layer 170 covers the two gate regions 160. Next, after the third insulating layer 170 is formed, a metal contact 180 may be formed on the third insulating layer 170. The metal contact 180 extends into the semiconductor substrate 110 to contact the implantation region of the semiconductor substrate 110 (i.e., the P-type region 116 and N-type region 118).

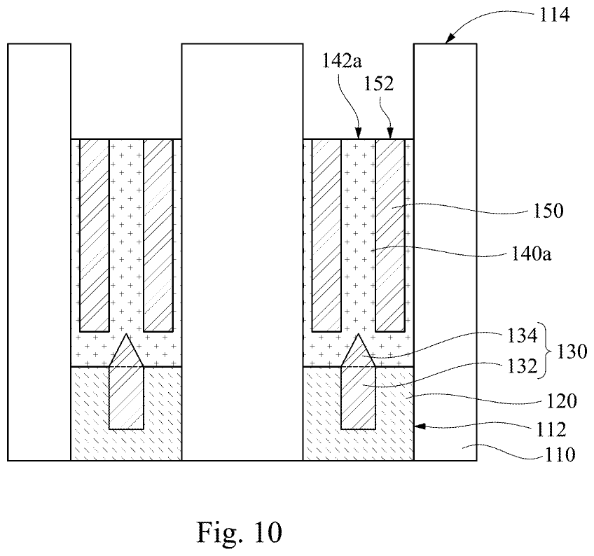

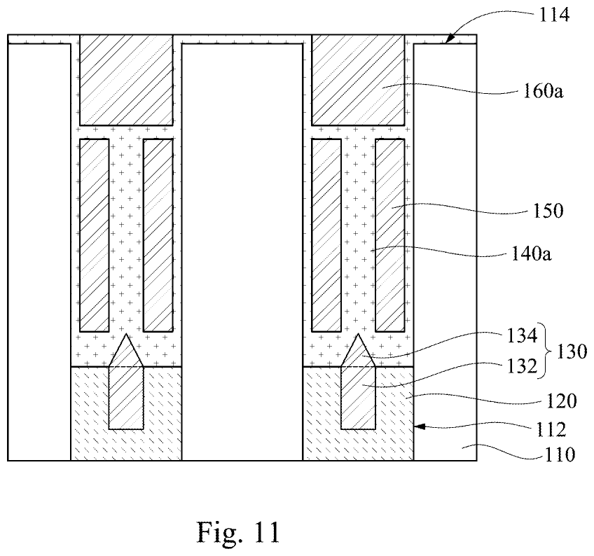

Reference is made to FIG. 10 and FIG. 11. FIG. 10 and FIG. 11 are partial cross-sectional views of different intermediate stages of a manufacturing method at one view angle according to another embodiment of the disclosure. In detail, FIG. 10 and FIG. 11 are partial cross-sectional views of the semiconductor structure 100a shown in FIG. 2 at different intermediate stages of the manufacturing method. The intermediate stages illustrated in FIG. 5, FIG. 6, FIG. 7, and FIG. 8 can be applied to the manufacturing method for forming the semiconductor structure 100a shown in FIG. 2 in this embodiment. After the structure shown in FIG. 8 is finished, the structures at the subsequent stages are shown in FIG. 10 and FIG. 11. As shown in FIG. 10, after the two source regions 150 are formed in the trench 112, the second insulating layer 140a may be etched such that a top surface 142a of the second insulating layer 140a is level with top surfaces 152 of the two source regions 150. In this embodiment, the semiconductor structure 100a includes a gate region 160a, instead of the two gate regions 160 of the semiconductor structure 100 shown in FIG. 1. As shown in FIG. 11, after the second insulating layer 140a is etched, the gate region 160a may be formed over the two source regions 150.

Referring back to FIG. 2, after forming the gate region 160a, the top surface 114 of the semiconductor substrate 110 can be implanted such that the semiconductor substrate 110 has an implantation region. For example, in some embodiments, the implantation region may include a P-type region 116 and an N-type region 118. In some embodiments, positions of the P-type region 116 and the N-type region 118 of the semiconductor substrate 110 correspond to positions of the gate region 160a. As shown in FIG. 2, after the semiconductor substrate 110 is implanted, a third insulating layer 170 may be formed on the gate region 160a. The third insulating layer 170 covers the gate region 160a. Next, after the third insulating layer 170 is formed, a metal contact 180 may be formed on the third insulating layer 170. The metal contact 180 extends into the semiconductor substrate 110 to contact the implantation region of the semiconductor substrate 110 (i.e., the P-type region 116 and N-type region 118).

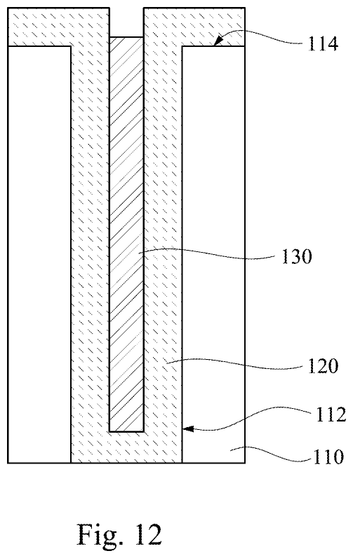

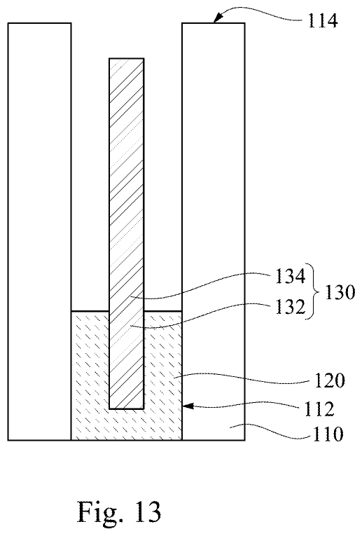

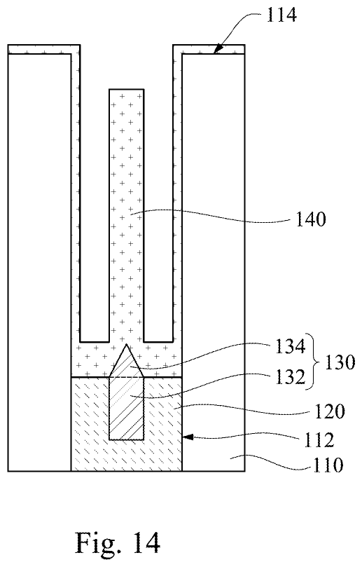

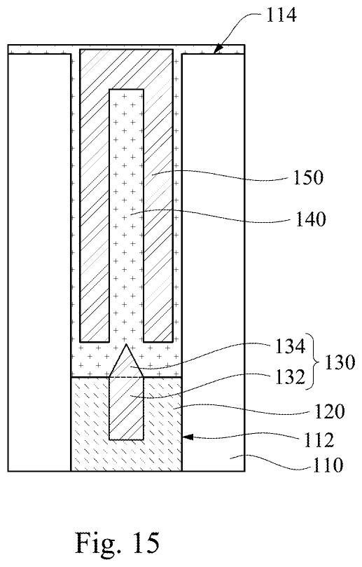

Reference is made to FIG. 12, FIG. 13, FIG. 14, and FIG. 15. FIG. 12, FIG. 13, FIG. 14, and FIG. 15 are partial cross-sectional views of different intermediate stages of a manufacturing method at another view angle according to an embodiment of the disclosure. In detail, FIG. 12, FIG. 13, FIG. 14, and FIG. 15 illustrate partial cross-sectional views of the contact of the two source regions 150 of the semiconductor structure 100 shown in FIG. 1 at different intermediate stages. As shown in FIG. 12, a trench 112 may be first formed in a semiconductor substrate 110 by an etching process. Later on, a first insulating layer 120 may be formed in the trench 112 and on a top surface 114 of the semiconductor substrate 110. For example, oxide may be used to form the first insulating layer 120. However, it is not limited thereto. After forming the first insulating layer 120, a floating portion 130 may be formed in the first insulating layer 120. In this embodiment, polysilicon is used to form the floating portion 130 in the first insulating layer 120.

As shown in FIG. 13, FIG. 14, and FIG. 15, the first insulating layer 120 and the floating portion 130 may be etched to expose the second portion 134 of the floating portion 130. After the second portion 134 of the floating portion 130 is exposed, a second insulating layer 140 may be formed on the first insulating layer 120 by wet oxidation. A part of the floating portion 130 is converted to the second insulating layer 140. In detail, in the wet oxidation process, the floating portion 130 including polysilicon can be partially converted to the second insulating layer 140. Moreover, two source regions 150 may be formed in the second insulating layer 140 after the second insulating layer 140 is formed.

Referring back to FIG. 3, a third insulating layer 170 may be formed on the second insulating layer 140. Next, after the third insulating layer 170 is formed, a metal contact 180 can be formed on the third insulating layer 170. The metal contact 180 extends into the semiconductor substrate 110 to contact the two source regions 150, which forms the structure shown in FIG. 3.

According to the foregoing recitations of the embodiments of the disclosure, it may be seen that in the semiconductor structure and the manufacturing method of the semiconductor structure of the present disclosure, by separating the two source regions of the semiconductor structure with the second insulating layer and by disposing the gate region(s) over the two source regions, structural defects may be avoided when forming the gate region(s). In addition, the two source regions disposed symmetrically along the longitudinal direction can enhance the electrical characteristics of the semiconductor structure. Therefore, the device reliability of the semiconductor structure may be improved. Moreover, by disposing the floating portion below the two source regions of the semiconductor structure, capacitance caused by the structural defects of the semiconductor structure may be reduced, thereby improving the performance of the semiconductor structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a first insulating layer disposed in a trench of a semiconductor substrate;
a floating portion disposed in the first insulating layer, wherein the floating portion has a first portion and a second portion extending from the first portion, and the first insulating layer surrounds the first portion of the floating portion;
a second insulating layer disposed on the first insulating layer and extending to a top surface of the semiconductor substrate, wherein the second insulating layer covers the second portion of the floating portion;
two source regions disposed in the second insulating layer, wherein the two source regions are separated by the second insulating layer and are disposed symmetrically along a longitudinal direction of the trench; and
a first gate region disposed over the two source regions.

2. The semiconductor structure of claim 1, further comprising a second gate region disposed over the two source regions, wherein the first gate region and the second gate region align with the two source regions, respectively, and the first gate region and the second gate region are separated by the second insulating layer and are disposed symmetrically along the longitudinal direction of the trench.

3. The semiconductor structure of claim 1, wherein a width of the first gate region is greater than a sum of widths of the two source regions.

4. The semiconductor structure of claim 1, wherein the semiconductor substrate has an implantation region, and a position of the implantation region corresponds to a position of the first gate region.

5. The semiconductor structure of claim 4, further comprising:
a metal contact extending into the semiconductor substrate to contact the implantation region of the semiconductor substrate; and
a third insulating layer disposed between the first gate region and the metal contact.

6. The semiconductor structure of claim 5, further comprising a second gate region disposed over the two source regions, wherein the third insulating layer covers the first gate region and the second gate region.

7. The semiconductor structure of claim 5, wherein the third insulating layer covers the first gate region.

8. The semiconductor structure of claim 1, wherein the floating portion comprises polysilicon.

9. A manufacturing method of a semiconductor structure, comprising:
forming a first insulating layer in a trench of a semiconductor substrate;
forming a floating portion in the first insulating layer, wherein the floating portion has a first portion and a second portion extending from the first portion;
etching the first insulating layer by wet etching to expose the second portion of the floating portion;
forming a second insulating layer on the first insulating layer by wet oxidation, wherein a part of the second portion of the floating portion is converted to the second insulating layer;
forming two source regions in the trench, wherein the two source regions are separated by the second insulating layer, and the two source regions are disposed symmetrically along a longitudinal direction of the trench; and
forming a first gate region over the two source regions.

10. The manufacturing method of claim 9, further comprising forming a second gate region over the two source regions, wherein the first gate region and the second gate region align with the two source regions, respectively, and the first gate region and the second gate region are separated by the second insulating layer and are disposed symmetrically along the longitudinal direction of the trench.

11. The manufacturing method of claim 9, wherein a width of the first gate region is greater than a sum of widths of the two source regions.

12. The manufacturing method of claim 9, further comprising etching the second insulating layer after forming the two source regions in the trench such that a top surface of the second insulating layer is level with a top surface of one of the two source regions.

13. The manufacturing method of claim 9, further comprising:
implanting a top surface of the semiconductor substrate such that the semiconductor substrate has an implantation region, wherein a position of the implantation region corresponds to a position of the first gate region.

14. The manufacturing method of claim 13, further comprising:
forming a third insulating layer on the first gate region, wherein the third insulating layer covers the first gate region; and
forming a metal contact on the third insulating layer, wherein the metal contact extends into the semiconductor substrate to contact the implantation region of the semiconductor substrate.

15. The manufacturing method of claim 9, wherein polysilicon is used to form the floating portion in the first insulating layer.
